(19) United States
(12) Patent Application Publication
(10) Pub. No.: US 2026/0011537 A1
(43) Pub. Date: Jan. 8, 2026

(54) PLASMA PROCESSING SYSTEM AND METHOD FOR ESTIMATING HEIGHT OF ANNULAR MEMBER

(71) Applicant: Tokyo Electron Limited, Tokyo (JP)

(72) Inventors: Takashi ARAMAKI, Miyagi (JP); Ryota KOITABASHI, Miyagi (JP); Lifu LI, Miyagi (JP); Hiroshi TSUJIMOTO, Miyagi (JP)

(73) Assignee: Tokyo Electron Limited, Tokyo (JP)

(21) Appl. No.: 19/324,327

(22) Filed: Sep. 10, 2025

Related U.S. Application Data
(63) Continuation of application No. PCT/JP2024/009524, filed on Mar. 12, 2024.

(30) Foreign Application Priority Data
Mar. 17, 2023 (JP) 2023-043197

(51) Int. Cl. H01J 37/32

(52) U.S. Cl. CPC H01J 37/32807; H01J 37/32642; H01J 37/32715; H01J 37/32733; H01J 2237/0041; H01J 2237/2007; H01J 2237/20235; H01J 2237/24578

(57) ABSTRACT

A plasma processing system includes control circuitry that executes (A) loading a jig substrate having a reference surface serving as a reference of the height of an annular member into the processing container and placing a jig substrate on a substrate support, (B) applying a voltage to a electrostatic chuck in a state where the gas is supplied into a processing container and attracting the jig substrate to a substrate placing surface in a plasma-less manner, (C) positioning a holder of a transfer robot above the substrate support and measuring, by a distance sensor, a distance to the reference surface of the jig substrate placed on the substrate placing surface and a distance to the annular member attached to the substrate support, and (D) estimating the height of the annular member based on measurement results of the distance to the reference surface and the distance to the annular member.

### CROSS-REFERENCE TO RELATED APPLICATIONS

This application is a bypass continuation application of international application No. PCT/JP2024/009524 having an international filing date of Mar. 12, 2024 and designating the United States, the international application being based upon and claiming the benefit of priority from Japanese Patent Application No. 2023-043197, filed on Mar. 17, 2023, the entire contents of each are incorporated herein by reference.

### TECHNICAL FIELD

The present disclosure relates to a plasma processing system and a method for estimating a height of an annular member.

### BACKGROUND

PTL 1 discloses a processing system for processing a substrate in a pressure-reduced environment. The processing system includes a processing chamber that performs desired processing on a substrate, a transfer chamber including a transfer device that transfers a substrate into or out of the processing chamber, and a controller that controls a processing process in the processing chamber. The transfer device includes a fork portion that holds the substrate on an upper surface and transfers the substrate, and a measurement device that is provided in the fork portion and measures an internal state of the processing chamber. The controller controls the processing process in the processing chamber based on the internal state of the processing chamber acquired by the measurement device. Further, the processing chamber may be provided with an electrostatic chuck that attracts and holds the substrate on an upper surface thereof, an edge ring disposed to surround a holding surface of the substrate in the electrostatic chuck in a plan view, and a link power supply that applies a direct-current voltage to the edge ring. The measurement device includes a distance sensor that measures a height position of the upper surface of the edge ring. The controller controls an amount of a direct-current voltage applied from the ring power supply based on the upper surface height position of the edge ring obtained by the measurement device.

### CITATION LIST

### Patent Documents

PTL 1: JP2022-69274A

### SUMMARY

The technique of the present disclosure accurately estimates a height of an annular member attached to a substrate support.

An aspect of the present disclosure provides a plasma processing system. The plasma processing system includes a plasma processing apparatus, a reduced-pressure transfer apparatus connected to the plasma processing apparatus and including a transfer robot configured to transfer a substrate, and a control device. The plasma processing apparatus includes a processing container configured to be depressurized, a substrate support which is provided in the processing container and includes a substrate placing surface and an electrostatic chuck configured to electrostatically attract the substrate to the substrate placing surface, and to which an annular member is attached so as to surround the substrate placing surface, an elevation mechanism configured to raise and lower the substrate relative to the substrate placing surface, and a gas supply configured to supply a gas into the processing container. The transfer robot includes a holder configured to hold the substrate to be transferred, and a distance sensor provided on the holder and configured to measure a distance from the holder. The control device executes (A) loading a jig substrate having a reference surface serving as a reference of a height of the annular member into the processing container by the transfer robot and placing the jig substrate on the substrate support by the elevation mechanism, (B) applying a voltage to the electrostatic chuck in a state where the gas is supplied into the processing container and attracting the jig substrate to the substrate placing surface in a plasma-less manner, (C) positioning the holder of the transfer robot above the substrate support and measuring, by the distance sensor, a distance to the reference surface of the jig substrate placed on the substrate placing surface and a distance to the annular member attached to the substrate support, and (D) estimating the height of the annular member based on measurement results of the distance to the reference surface and the distance to the annular member.

According to the present disclosure, the height of the annular member attached to the substrate support can be accurately estimated.

### BRIEF DESCRIPTION OF DRAWINGS

FIG. 1 is a plan view showing a schematic configuration of a plasma processing system according to the present embodiment.

FIG. 2 is a diagram showing a schematic configuration of a transfer robot provided in a transfer module.

FIG. 3 is a bottom view showing a schematic configuration of a fork.

FIG. 4 is a vertical sectional view showing a schematic configuration of a processing module.

FIG. 5 is a partially enlarged view of FIG. 4.

FIG. 6 is a partially enlarged cross-sectional view of an electrostatic chuck.

FIG. 7 is a plan view of an example of a jig wafer serving as a jig substrate used for estimation of a height of an edge ring.

FIG. 8 is a flowchart showing an example of a method for estimating the height of the edge ring.

FIG. 9 is a view showing positions of the fork and a distance sensor with respect to a wafer support when the height of the edge ring is estimated.

FIG. 10 is a view illustrating another example of steps S3 and S4.

FIG. 11 is a plan view schematically showing another example of the jig wafer.

FIG. 12 is a cross-sectional view schematically showing another example of the jig wafer.

FIG. 13 is a diagram showing results of a test performed to check repeatability of an estimation result of the height of the edge ring according to the technique of the present disclosure.

FIG. 14 is a top view showing another example of an annular member.

### DETAILED DESCRIPTION

In a manufacturing process of a semiconductor device or the like, a substrate such as a semiconductor wafer (hereinafter referred to as “wafer”) is subjected to substrate processing such as etching processing using a plasma, that is, plasma processing. The plasma processing is performed in a state where the substrate is placed on a substrate support in a pressure-reduced processing container.

A member having an annular shape in a plan view, such as an edge ring or a cover ring, is placed on the above-described substrate support to surround the substrate on the substrate support. The edge ring (also referred to as a focus ring) is an annular member disposed to be adjacent to the substrate on the substrate support, and the cover ring is an annular member disposed to cover an outer surface of the edge ring. The edge ring and the cover ring are etched and worn out by being exposed to plasma. When the edge ring or the cover ring is consumed, an appropriate plasma processing result may not be obtained. Specifically, for example, when the edge ring is worn, a shape of a sheath of the plasma changes, and as a result, an appropriate plasma processing result may not be obtained.

Therefore, in the related art, a height of an annular member such as an edge ring placed on a substrate support (in other words, the degree of wear of the annular member) is estimated using a sensor. For example, an amount of wear of the edge ring may be estimated based on a measurement distance from a sensor provided on a transfer arm of the substrate transfer apparatus that transfers the substrate for the processing container to a surface of the edge ring and a measurement distance from the sensor to a surface of the substrate support.

However, when the height of the annular member such as the edge ring is estimated based on the distance from the sensor to the surface of the substrate support (specifically, the substrate placing surface on which the substrate is placed), the estimation result may not be accurate. For example, the surface of the substrate support may intentionally have unevenness, and in this case, the estimation result of the height of the annular member varies depending on the distance to which part of an uneven surface forming the unevenness of the surface of the substrate support is measured by the sensor. However, when the unevenness is small, it is difficult to select the distance to which part of the uneven surface on the substrate support surface is measured by the sensor.

It is also conceivable to estimate the height of an annular member such as an edge ring by placing a dummy substrate made of silicon or the like on the substrate support based on the distance from the dummy substrate to the sensor. However, if the dummy substrate is simply placed on the substrate support, the amount of charge on a substrate placing surface of the substrate support varies depending on the timing of measuring the distance. As a result, an attraction force of the dummy substrate to the substrate support also varies. Therefore, the distance from the dummy substrate to the sensor cannot be accurately measured, and the height of the annular member such as the edge ring cannot be accurately estimated either.

Further, it is also conceivable to estimate the amount of wear based on a measurement result of the height of the edge ring before the plasma processing and a measurement result of the height of the current edge ring. However, in this estimation method, when a tip of the transfer arm on which the sensor is provided sags due to its own weight during the repetition of the loading and unloading of the substrate, the measurement result of the height of the current edge ring may be inaccurate, and the amount of wear may not be accurately estimated.

Therefore, the technique according to the present disclosure accurately estimates the height of the annular member attached to the substrate support.

Hereinafter, a plasma processing system and a method for estimating the height of an annular member according to the present embodiment will be described with reference to the drawings. Like reference numerals will be given to like parts having substantially the same functions throughout the specification and the drawings, and redundant description thereof will be omitted.

### <Plasma Processing System>

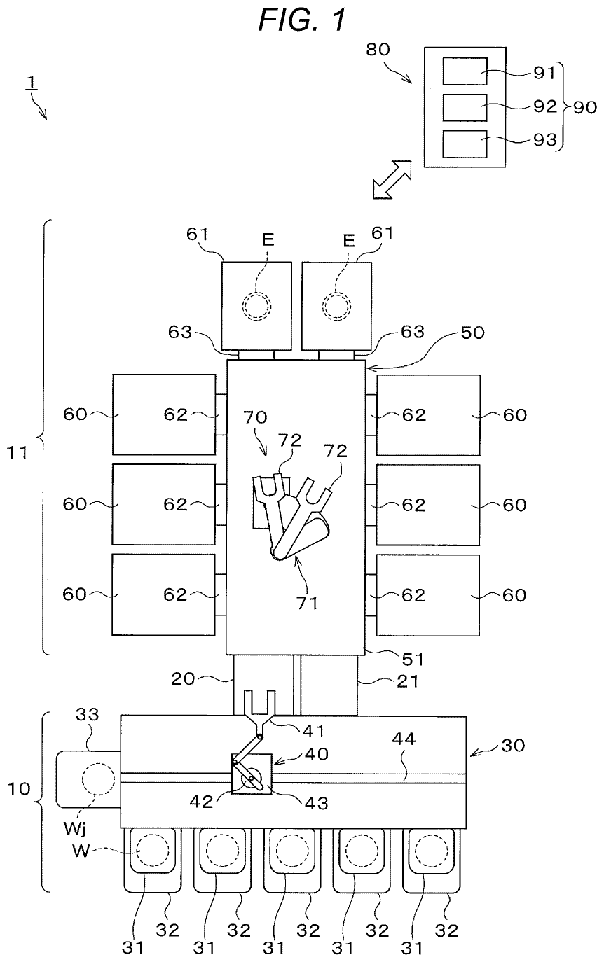

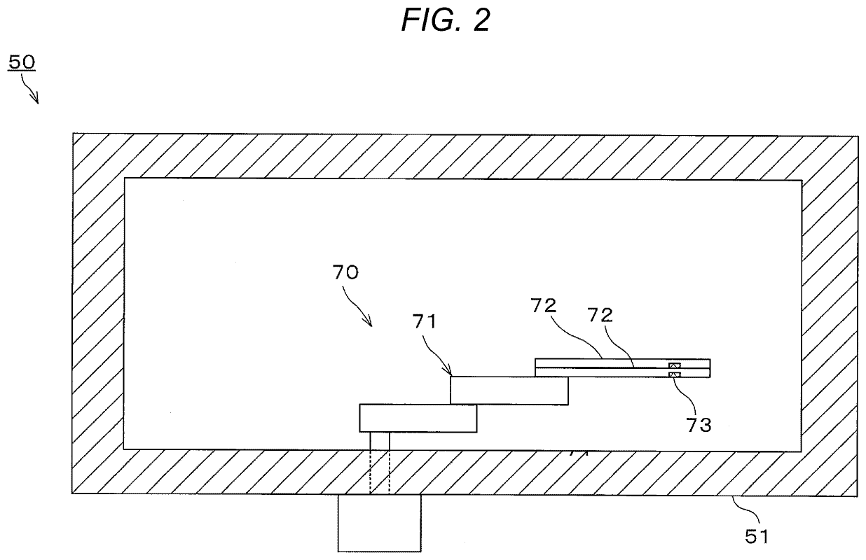

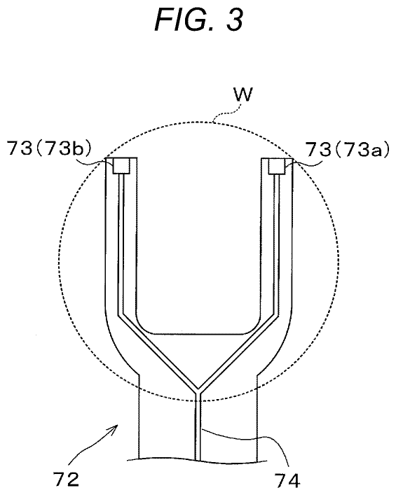

FIG. 1 is a plan view showing a schematic configuration of the plasma processing system of the present embodiment. FIG. 2 is a diagram showing a schematic configuration of a transfer robot provided in a transfer module (described later). FIG. 3 is a bottom view showing a schematic configuration of a fork described later.

In a plasma processing system 1 in FIG. 1, a wafer W that is a substrate is processed. Specifically, the wafer W is subjected to the substrate processing such as the etching processing using the plasma, that is, the plasma processing.

The plasma processing system 1 includes an atmospheric section 10 operating under an atmospheric pressure atmosphere and a decompression section 11 operating under a pressure-reduced atmosphere, and the atmospheric section 10 and the decompression section 11 are integrally connected to each other via load-lock modules 20 and 21. The atmospheric section 10 includes an atmospheric module for performing desired processing on the wafer W under an atmospheric pressure atmosphere. The decompression section 11 includes a decompression module for performing desired processing on the wafer W under a pressure-reduced atmosphere (vacuum atmosphere).

The load-lock modules 20 and 21 are connected to a loader module 30 of the atmospheric section 10 and a transfer module 50 of the decompression section 11 through gate valves. The load lock-modules 20 and 21 are configured to temporarily hold the wafer W. Further, each of the load-lock modules 20 and 21 is a load lock apparatus configured such that an inner space thereof can be switched between an atmospheric pressure atmosphere and a pressure-reduced atmosphere.

The atmospheric section 10 includes the loader module 30 serving as an atmospheric pressure transfer device operating in an atmospheric pressure atmosphere and having a transfer device 40 described later, and load ports 32 on each of which a hoop 31 is placed. The hoop 31 is a storage container capable of storing a plurality of wafers W. An orienter module (not shown) that adjusts an orientation of the wafer W in a horizontal direction, a buffer module (not shown) that temporarily stores the plurality of wafers W, and the like may be connected to the loader module 30.

The loader module 30 has a rectangular housing, and an inner space of the housing is maintained in an atmospheric pressure atmosphere. A plurality of load ports 32, for example, five load ports 32, are disposed side by side on one side surface forming a long side of a housing of the loader module 30. The load-lock modules 20 and 21 are disposed side by side on the other longitudinal side the housing of the loader module 30.

In one embodiment, a storage module 33 serving as a substrate storage that stores a jig wafer Wj serving as a jig substrate is connected to one side surface forming a short side of the housing of the loader module 30. The storage module 33 may also function as the above-described buffer module.

The transfer device 40 configured to hold and transfer the wafer W is provided in the housing of the loader module 30. The transfer device 40 includes a transfer arm 41 that supports the wafer W during transfer, a rotor 42 that rotatably supports the transfer arm 41, and a base 43 on which the rotor 42 is placed. Further, a guide rail 44 extending in the longitudinal direction of the loader module 30 is disposed in the loader module 30. The base 43 is disposed on the guide rail 44, and the transfer device 40 is configured to be movable along the guide rail 44.

The decompression section 11 includes the transfer module 50 serving as a reduced-pressure transfer apparatus and processing modules 60 serving as a plasma processing apparatus. The decompression section 11 may include accommodation modules 61 serving as a member storage. An inner space of each of the transfer module 50 and the processing module 60 (specifically, an inner space of each of a pressure-reduced transfer space 51 and a chamber 100 (described later)) is maintained in a pressure-reduced atmosphere, and an inner space of the accommodation module 61 is also maintained in a pressure-reduced atmosphere. A plurality of processing modules 60, for example, six processing modules 60, and a plurality of accommodation modules 61, for example, two accommodation modules 61, are provided for one transfer module 50. The number and disposition of the processing modules 60 are not limited to those in the present embodiment and may be arbitrarily set as long as at least one processing module including a wafer support (described later) is provided. The number and disposition of the accommodation modules 61 are also not limited to those in the present embodiment and can be arbitrarily set. For example, at least one accommodation module 61 is provided.

The transfer module 50 is configured to transfer the wafer W in the inner space thereof. The transfer module 50 may also be configured to transfer an edge ring E (described later) in the inner space thereof.

The transfer module 50 includes the pressure-reduced transfer space 51 having a housing of a polygonal shape in plan view (in the shown example, a quadrangular shape in plan view). The pressure-reduced transfer space 51 is connected to the load-lock modules 20 and 21.

The transfer module 50 is configured to transfer the wafer W loaded in the load-lock module 20 to one processing module 60 and unload the wafer W subjected to desired plasma processing in the processing module 60 into the load-lock module 21.

Further, the transfer module 50 may transfer the edge ring E in the accommodation module 61 to one processing module 60 and unload the edge ring E in the processing module 60 into the accommodation module 61.

The processing module 60 performs the desired plasma processing, for example, the etching processing, on the wafer W transferred from the transfer module 50. Further, the processing modules 60 are connected to the transfer module 50 through gate valves 62. A specific configuration of the processing module 60 will be described later.

The accommodation module 61 accommodates the edge ring E. Further, the accommodation module 61 is connected to the transfer module 50 through a gate valve 63.

A transfer robot 70 is provided in the pressure-reduced transfer space 51 of the transfer module 50. The transfer robot 70 is configured to hold and transfer the wafer W. The transfer robot 70 is also configured to hold and transfer the edge ring E.

The transfer robot 70 includes a transfer arm 71 that is configured to be swivelled, retracted, and elevated in a state of holding the wafer W. A tip of the transfer arm 71 branches into forks 72 and 72 serving as two holders. The forks 72 and 72 are configured to hold the wafer W and the edge ring E to be transferred, respectively.

Further, as shown in FIG. 2, at least one of the forks 72 and 72 is provided with a distance sensor 73. The distance sensor 73 measures a distance from the fork 72 (specifically, the distance sensor 73) to a target point.

For example, as shown in FIG. 3, the fork 72 has a bifurcated shape having a width smaller than a diameter of the wafer W. The distance sensor 73 includes, for example, one distance sensor 73a at one tip of the bifurcated part of the fork 72 and one distance sensor 73b at the other tip.

As a distance measurement method using the distance sensor 73, a method that can perform non-contact measurement in a pressure-reduced atmosphere, for example, a method based on light is adopted. In this case, for example, the distance sensor 73 emits light for distance measurement to a target object and receives reflected light, and a unit controller (not shown) connected to the distance sensor 73 via an optical fiber 74 measures a distance from the fork 72 (specifically, the distance sensor 73) to the target point based on a light reception result obtained by the distance sensor 73.

A more specific example of the distance measurement method using the distance sensor 73 is a white light confocal method. When the white light confocal method is adopted, for example, white light supplied from a light source (not shown) such as an LED provided in the unit controller is emitted from the distance sensor 73 to the target object such that each wavelength in the white light is focused at different heights. Then, only the light having the wavelength focused on the target object is input to the unit controller as the reflected light via the distance sensor 73. The unit controller calculates the distance from the fork 72 (specifically, the distance sensor 73) to the target point based on the wavelength of the input light. The distance sensor 73 is disposed such that an optical axis of the white light is substantially parallel to a vertical direction.

The white light confocal method is merely an example, and may be any method as long as the distance can be measured with a desired accuracy (for example, a resolution in the height direction is 15 μm or less, and a resolution in the horizontal direction is about 0.1 mm).

As described above, the distance sensor 73 and the unit controller are connected to each other via the optical fiber 74, and the above-described light for distance measurement (white light) and reflected light are transmitted through the optical fiber. An optical switch (not shown) is interposed in the optical fiber 74.

The unit controller and the optical switch are provided, for example, in a space having an atmospheric atmosphere outside the pressure-reduced transfer space 51. Further, the unit controller calculates, i.e., measures, the distance from the fork 72 (specifically, the distance sensor 73) to the target point based on the light reception result obtained by the distance sensor 73 as described above, and controls the measurement by the distance sensor 73 under the control of a control device 80 (i.e., control circuitry) described later.

In the transfer module 50, the wafer W held in the load-lock module 20 is received by the transfer arm 71 and is loaded into the processing module 60. Further, the wafer W subjected to desired processing in the processing module 60 is received by the transfer arm 71 and is unloaded into the load-lock module 21.

Further, in the transfer module 50, the transfer arm 71 may receive the edge ring E in the accommodation module 61 and load the edge ring E into the processing module 60. Further, in the transfer module 50, the transfer arm 71 may receive the edge ring E in the processing module 60 and unload the edge ring E into the accommodation module 61.

The plasma processing system 1 further includes the control device 80. In one embodiment, the control device 80 processes computer-executable instructions for causing the plasma processing system 1 to execute various steps described in the present disclosure. The control device 80 may be configured to control each of other components of the plasma processing system 1 such that the plasma processing system 1 executes the various steps to be described here. In one embodiment, the control device 80 may be partially or entirely included in the components of the plasma processing system 1. For example, the control device 80 may include a computer 90. For example, the computer 90 may include a processor (central processing unit (CPU)) 91, a storage unit 92, and a communication interface 93. The processor 91 may be configured to perform various control operations and calculations based on a program stored in the storage unit 92. The storage unit 92 may include a random access memory (RAM), a read only memory (ROM), a hard disk drive (HDD), a solid state drive (SSD), or a combination thereof. The communication interface 93 may communicate with the components of the plasma processing system 1 through a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

### <Wafer Processing in Plasma Processing System 1>

Next, an example of wafer processing using the plasma processing system 1 configured as described above will be described.

First, the wafer W is acquired from the desired hoop 31 by the transfer device 40 and loaded into the load-lock module 20 by the transfer device 40. Next, the load-lock module 20 is sealed and decompressed. Thereafter, the inner space of the load-lock module 20 communicates with the inner space of the transfer module 50.

Next, the wafer W is held by the transfer robot 70 and is transferred from the load-lock module 20 to the transfer module 50.

Next, the gate valve 62 corresponding to the desired processing module 60 is open, and the wafer W is loaded into the desired processing module 60 by the transfer robot 70. Then, the gate valve 62 is closed, and the wafer W is subjected to desired processing in the processing module 60. The processing performed on the wafer W in the processing module 60 will be described later.

Next, the gate valve 62 is open, and the wafer W is unloaded from the processing module 60 by the transfer robot 70. Then, the gate valve 62 is closed.

Next, the wafer W is loaded into the load-lock module 21 by the transfer robot 70. When the wafer W is loaded into the load-lock module 21, the load-lock module 21 is sealed and exposed to the atmosphere. Then, the inner space of the load-lock module 21 communicates with the inner space of the loader module 30.

Next, the wafer W is held by the transfer device 40 and is returned to the desired hoop 31 to be accommodated from the load-lock module 21 through the loader module 30. This ends the wafer processing using the plasma processing system 1.

### <Processing Module 60>

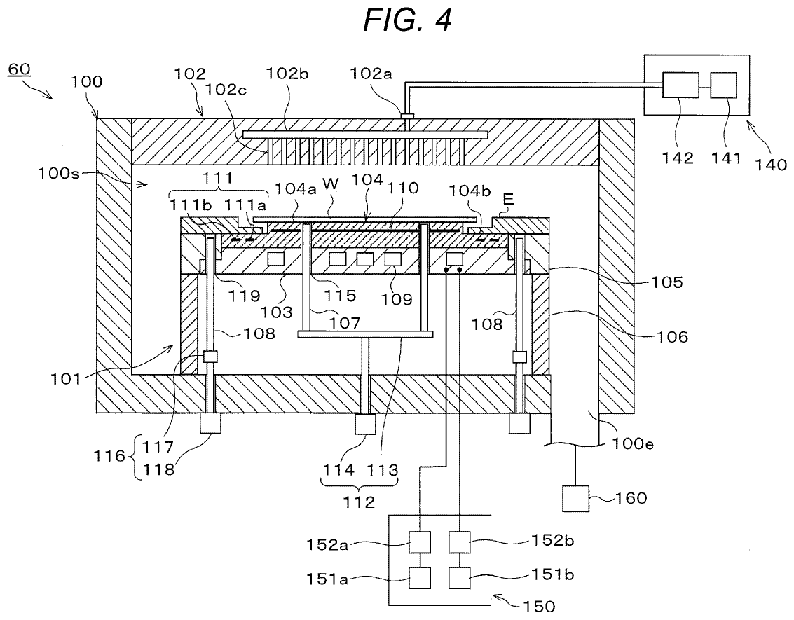

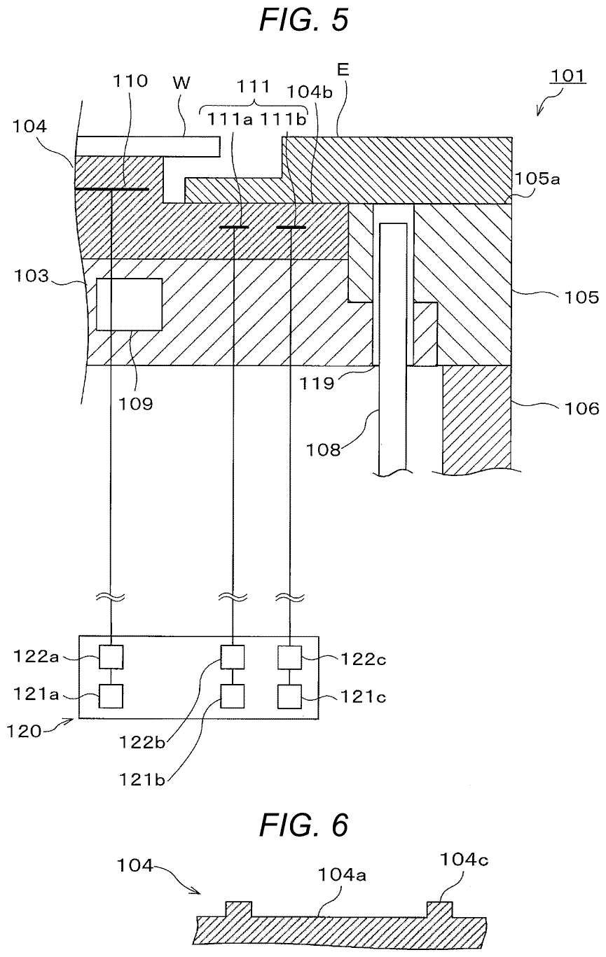

Next, the processing module 60 will be described with reference to FIGS. 4 to 6. FIG. 4 is a vertical sectional view showing a schematic configuration of the processing module 60. FIG. 5 is a partially enlarged view of FIG. 4. FIG. 6 is a partially enlarged cross-sectional view of an electrostatic chuck described later.

As shown in FIG. 4, the processing module 60 includes the chamber 100 serving as a processing container, a gas supply mechanism 140, a radio frequency (RF) power supply unit 150, and an exhaust system 160. Further, the processing module 60 also includes a voltage application unit 120 (see FIG. 5). The processing module 60 further includes a wafer support 101 serving as a substrate support and an upper electrode 102.

The chamber 100 has an inner space that is configured to be decompressed, and defines a processing space 100s in which the plasma is generated. Further, the wafer support 101 and the like are provided in the chamber 100. For example, aluminum can be used as a material of the chamber 100. Further, the chamber 100 is connected to a ground potential.

For example, the wafer support 101 is disposed in a lower region of the chamber 100. The upper electrode 102 is disposed above the wafer support 101 and may function as a part of a ceiling of the chamber 100.

The wafer support 101 is configured to support the wafer W. In one embodiment, the wafer support 101 includes a lower electrode 103, an electrostatic chuck 104, a support 105, an insulator 106, and a lifter 107. The wafer support 101 may include a lifter 108. The wafer support 101 is configured to receive the edge ring E. Specifically, the wafer support 101 is also configured to support the edge ring E. The wafer support 101 may or may not include the edge ring E as a constituent member thereof.

The lower electrode 103 is made of a conductive material such as aluminum or the like. A lower outer peripheral portion of the lower electrode 103 and an upper inner peripheral portion of the support 105 may be formed to overlap with each other in a plan view. In one embodiment, a flow path 109 of a temperature-controlled fluid is formed in the lower electrode 103. The temperature-controlled fluid is supplied to the flow path 109 from a chiller unit (not shown) provided outside the chamber 100. The temperature-controlled fluid supplied to the flow path 109 returns to the chiller unit. For example, the wafer support 101 (specifically, the electrostatic chuck 104), the wafer W, or the edge ring E can be cooled to a predetermined temperature by circulating, for example, low-temperature brine as the temperature-controlled fluid through the flow path 109. For example, the wafer support 101 (specifically, the electrostatic chuck 104), the wafer W, or the edge ring E can be heated to a predetermined temperature by circulating, for example, high-temperature brine as the temperature-controlled fluid through the flow path 109.

When a temperature control mechanism is provided in the wafer support 101, a form of the temperature control mechanism is not limited to the flow path 109 and may be, for example, another form such as a resistance heating type heater. Further, a member in which the temperature control mechanism is disposed in the wafer support 101 is not limited to the lower electrode 103 and may be another member.

The electrostatic chuck 104 is a member configured to electrostatically attract at least the wafer W, and is provided on the lower electrode 103. Further, the electrostatic chuck 104 may also be configured to electrostatically attract the edge ring E. In one embodiment, a central portion of the electrostatic chuck 104 constitutes a substrate stage. Further, in one embodiment, in the electrostatic chuck 104, an upper surface of the central portion is formed to be higher than an upper surface of a peripheral portion. In one embodiment, the wafer W is placed on an upper surface 104a of the central portion of the electrostatic chuck 104, and the edge ring E is placed on an upper surface 104b of the peripheral portion of the electrostatic chuck 104. That is, in one embodiment, the upper surface 104a of the central portion of the electrostatic chuck 104 serves as a wafer placing surface as a substrate placing surface on which the wafer W is placed, and the upper surface 104b of the peripheral portion of the electrostatic chuck 104 serves as a ring placing surface on which the edge ring E is placed to surround the substrate placing surface.

The edge ring E is a member disposed to surround the wafer placing surface, that is, a member disposed to surround the wafer W. Specifically, the edge ring E is a member disposed to surround the wafer W placed on the electrostatic chuck 104. In one embodiment, the edge ring E is disposed to surround the central portion having a higher position of the upper surface than the peripheral portion in the electrostatic chuck 104. The edge ring E is formed to have an annular shape in plan view. Si, SiO₂, or the like is used as a material of the edge ring E.

The central portion of the electrostatic chuck 104 is provided with an electrode 110 for electrostatically attracting the wafer W to the upper surface 104a of the central portion.

Further, the peripheral portion of the electrostatic chuck 104 may be provided with an electrode 111 for electrostatically attracting the edge ring E to the upper surface 104b of the peripheral portion. The electrode 111 is, for example, a bipolar electrode that includes a pair of electrodes 111a and 111b formed at positions different from each other.

The electrostatic chuck 104 has a configuration in which the electrodes 110 and 111 are interposed between insulating members made of, for example, an insulating material.

As shown in FIG. 5, the voltage application unit 120 is connected to the electrode 110 to generate an electric force (specifically, for example, a coulomb force) for electrostatically attracting the wafer W.

The voltage application unit 120 includes a direct-current power supply 121a and a switch 122a.

The direct-current power supply 121a is connected to the electrode 110 via the switch 122a and applies, to the electrode 110, a voltage for electrostatically attracting the wafer W. The direct-current power supply 121a can selectively apply a positive voltage or a negative voltage to the electrode 110.

The voltage application unit 120 may be connected to the electrode 111 to generate an electric force for electrostatically attracting the edge ring E. When the electrode 111 is a bipolar electrode, any one of voltages of polarities different from each other or voltages of the same polarity may be selectively applied to the pair of electrodes 111a and 111b from the voltage application unit 120.

The voltage application unit 120 includes, for example, two direct-current power supplies 121b and 121c and two switches 122b and 122c.

The direct-current power supply 121b is connected to the electrode 111a via, for example, the switch 122b and selectively applies, to the electrode 111a, a positive voltage for electrostatically attracting the edge ring E or a negative voltage.

The direct-current power supply 121c is connected to the electrode 111b via, for example, the switch 122c and selectively applies, to the electrode 111b, a positive voltage for electrostatically attracting the edge ring E or a negative voltage.

In the present embodiment, the central portion of the electrostatic chuck 104 provided with the electrode 110 and the peripheral portion of the electrostatic chuck 104 provided with the electrode 111 are integrated with each other. However, the central portion and the peripheral portion may be separate bodies.

Further, in the present embodiment, the electrode 111 for attracting and holding the edge ring E is a bipolar electrode. However, the electrode 111 may be a unipolar electrode.

As shown in FIG. 6, the upper surface 104a of the central portion of the electrostatic chuck 104 may have a plurality of protruding portions 104c. Accordingly, the attraction force of the wafer W to the electrostatic chuck 104 by the residual charges can be reduced when the application of the voltage to the electrode 110 is stopped. The protruding portions 104c are provided at equal intervals, for example. The protruding portion 104c is formed in, for example, a columnar shape having a diameter of 300 μm to 500 μm and a height of 5 μm to 30 μm.

Further, as shown in FIG. 5, for example, the central portion of the electrostatic chuck 104 is formed to have a diameter smaller than a diameter of the wafer W. When the wafer W is placed on the upper surface 104a of the central portion of the electrostatic chuck 104, the peripheral portion of the wafer W horizontally protrudes outward from the central portion of the electrostatic chuck 104.

Further, the edge ring E has a stepped portion formed on an upper portion thereof, and an upper surface of an outer peripheral portion of the edge ring E is formed to be higher than an upper surface of an inner peripheral portion of the edge ring E. The inner peripheral portion of the edge ring E is positioned below the peripheral portion of the wafer W that horizontally protrudes outward from the central portion of the electrostatic chuck 104. In other words, an inner diameter of the edge ring E is smaller than an outer diameter of the wafer W.

The support 105 is a member formed to have an annular shape in plan view using, for example, an insulating material such as quartz, and is disposed to surround the lower electrode 103 and the electrostatic chuck 104.

A gas discharge hole (not shown) may be formed in the upper surface 104a of the central portion of the electrostatic chuck 104 to discharge a heat transfer gas into a gap between a back surface of the placed wafer W and the upper surface 104a. The heat transfer gas from a gas supply (not shown) is supplied from the gas discharge hole. The gas supply may include one or more gas sources and one or more pressure controllers. In one embodiment, for example, the gas supply is configured to supply the heat transfer gas from the gas source to the gas supply hole through the pressure controller.

Further, the gas discharge hole (not shown) may be formed in the upper surface 104b of the peripheral portion of the electrostatic chuck 104 to discharge the heat transfer gas into a gap between a back surface of the placed edge ring E and the upper surface 104b. The heat transfer gas from a gas supply (not shown) is supplied from the gas discharge hole. The gas supply may include one or more gas sources and one or more pressure controllers. In one embodiment, for example, the gas supply is configured to supply the heat transfer gas from the gas source to the gas supply hole through the pressure controller.

The insulator 106 in FIG. 4 is a cylindrical member formed of a ceramic material or the like and supports the support 105. For example, the insulator 106 is formed to have an outer diameter equal to an outer diameter of the support 105 and supports a peripheral edge portion of the support 105.

The lifter 107 is a member that is elevated with respect to the upper surface 104a of the central portion of the electrostatic chuck 104. The lifter 107 is formed to have a columnar shape using, for example, a ceramic material. When the lifter 107 is raised, an upper end thereof protrudes from the upper surface 104a and can support the wafer W.

Three or more lifters 107 are provided at intervals from each other and are provided to extend in an up-down direction.

The lifter 107 is elevated by an actuator 112. The actuator 112 includes, for example, a support member 113 that supports a plurality of lifters 107, and a driving unit 114 that generates a driving force for elevating the support member 113 to elevate the plurality of lifters 107. The driving unit 114 includes, for example, a motor (not shown) as a driving source that generates the driving force.

The lifter 107 is inserted into an insertion hole 115 having an upper end open to the upper surface 104a of the central portion of the electrostatic chuck 104. For example, the insertion hole 115 is formed to extend downward from the upper surface 104a of the central portion of the electrostatic chuck 104 to reach a bottom surface of the lower electrode 103.

The lifter 107 as described above can transfer the wafer W between the wafer support 101 and the transfer arm 71 of the transfer robot 70.

Further, the lifter 107 and the actuator 112 form an elevation mechanism that raises and lowers the wafer W relative to the wafer placing surface.

The lifter 108 is an elevation member that is raised and lowered relative to the upper surface 104b of the peripheral portion of the electrostatic chuck 104, and is formed into a columnar shape using, for example, ceramic as a material. In one embodiment, the lifter 108 is configured such that an upper end thereof can protrude from an upper surface 105a of the support 105 when the lifter 108 is raised.

Three or more lifters 108 are provided at intervals from each other along the circumferential direction of the electrostatic chuck 104 and are provided to extend in the up-down direction.

The lifter 108 is raised and lowered by an actuator 116. For example, the actuator 116 is provided for each lifter 108 and includes a support member 117 that movably supports the lifter 108 in the horizontal direction. For example, the support member 117 has a thrust bearing in order to movably support the lifter 108 in the horizontal direction. The actuator 116 also includes a driving unit 118 that generates a driving force for raising and lowering the support member 117 to raise and lower the lifter 108. The driving unit 118 includes, for example, a motor (not shown) as a driving source that generates the driving force.

In one embodiment, the lifter 108 is inserted into an insertion hole 119 having an upper end open to the upper surface 105a of the support 105. The insertion hole 119 is formed, for example, to extend downward from an upper surface of an inner peripheral portion of the support 105 to a bottom surface of the lower outer peripheral portion of the lower electrode 103.

The edge ring E can be transferred between the wafer support 101 and the transfer arm 71 of the transfer robot 70 by the lifter 108.

Further, the lifter 108 and the actuator 116 constitute another elevation mechanism that raises and lowers the edge ring E relative to the wafer support 101.

The upper electrode 102 also functions as a gas supply, that is, a shower head that discharges one or more gases from the gas supply mechanism 140 into the chamber 100. In one embodiment, the upper electrode 102 has a gas inlet 102a, a gas diffusion space 102b, and a plurality of gas outlets 102c. For example, the gas inlet 102a is in fluid communication with the gas supply mechanism 140 and the gas diffusion space 102b. The plurality of gas outlets 102c are in fluid communication with inner spaces of the gas diffusion space 102b and the chamber 100. In one embodiment, the upper electrode 102 is configured to supply one or more gases such as processing gases from the gas inlet 102a to the chamber 100 through the gas diffusion space 102b and the plurality of gas outlets 102c.

The gas supply mechanism 140 may include one or more gas sources 141 and one or more flow rate controllers 142. In one embodiment, for example, the gas supply mechanism 140 is configured to supply one or more gases from the respective corresponding gas sources 141 to the gas inlet 102a via the respective corresponding flow rate controllers 142. Each flow rate controller 142 may include, for example, a mass flow controller or a pressure-controlled flow rate controller. Further, the gas supply mechanism 140 may include one or more flow rate modulation devices that modulate or pulse flow rates of one or more gases.

The RF power supply unit 150 is configured to supply an RF power, for example, one or more RF signals, to one or more electrodes such as the lower electrode 103, the upper electrode 102, or both the lower electrode 103 and the upper electrode 102. Accordingly, the plasma is generated from one or more processing gases supplied into the chamber 100, that is, the processing space 100s. Accordingly, the RF power supply unit 150 may function as at least a part of a plasma generator that generates the plasma in the chamber 100. Specifically, the plasma generator is configured to generate the plasma from one or more gases in the chamber 100. For example, the RF power supply unit 150 includes two RF generation units (RF) 151a and 151b and two matching circuits (MC) 152a and 152b. In one embodiment, the RF power supply unit 150 is configured to supply a first RF signal from the first RF generation unit 151a to the lower electrode 103 through the first matching circuit 152a. For example, the first RF signal may have a frequency within a range of 27 MHz to 100 MHz.

Further, in one embodiment, the RF power supply unit 150 is configured to supply a second RF signal from the second RF generation unit 151b to the lower electrode 103 through the second matching circuit 152b. For example, the second RF signal may have a frequency within a range of 400 kHz to 13.56 MHz. Further, instead of the second RF generation unit 151b, a Direct Current (DC) pulse generator may be used.

Although it is not illustrated, other embodiments may be considered in the present disclosure. For example, in an alternative embodiment, the RF power supply unit 150 may be configured to supply the first RF signal from the RF generation unit to the lower electrode 103, supply the second RF signal from another RF generation unit to the lower electrode 103, and supply a third RF signal from still another RF generation unit to the lower electrode 103. In addition, in another alternative embodiment, a DC voltage may be applied to the upper electrode 102.

Further, in various embodiments, amplitudes of one or more RF signals (that is, the first RF signal, the second RF signal, and the like) may be pulsated or modulated. The amplitude modulation may include pulsating the RF signal amplitude between an ON state and an OFF state, or between two or more different ON states.

The exhaust system 160 may be connected to an exhaust port 100e provided, for example, at the bottom of the chamber 100. The exhaust system 160 may include a pressure valve and a vacuum pump. The vacuum pump may include a turbo molecular pump, a roughing pump or a combination thereof.

### <Wafer Processing in Processing Module 60>

Next, an example of the wafer processing performed by the processing module 60 will be described. In the processing module 60, the wafer W is subjected to the plasma processing such as the etching processing.

First, the wafer W is loaded into the chamber 100 by the transfer robot 70, and the wafer W is placed on the electrostatic chuck 104 by elevating the lifter 107. Thereafter, a direct-current voltage is applied from the direct-current power supply 121a to the electrode 110 of the electrostatic chuck 104. Accordingly, the wafer W is electrostatically attracted and held by the electrostatic chuck 104. Further, after the wafer W is loaded, the inner space of the chamber 100 is decompressed to a predetermined vacuum level by the exhaust system 160.

Next, the processing gas is supplied from the gas supply mechanism 140 to the processing space 100s via the upper electrode 102. Further, the RF power supply unit 150 supplies RF power HF for plasma generation to the lower electrode 103. Accordingly, the processing gas is excited to generate plasma. At this time, the RF power supply unit 150 may supply RF power LF for ion attraction. Then, the wafer W is subjected to plasma processing by the action of the generated plasma.

During the plasma processing, direct-current voltages are applied from the direct-current power supplies 121b and 121c to the electrode 111 of the electrostatic chuck 104. Accordingly, the edge ring E may be electrostatically attracted and held by the electrostatic chuck 104. Further, during the plasma processing, the heat transfer gas may be discharged toward bottom surfaces of the wafer W and the edge ring E attracted and held by the electrostatic chuck 104.

In order to end the plasma processing, the supply of the RF power HF from the RF power supply unit 150 and the supply of the processing gas from the gas supply mechanism 140 are stopped. When the RF power LF is supplied during the plasma processing, the supply of the RF power LF is also stopped. Thereafter, the attraction and holding of the wafer W by the electrostatic chuck 104 is stopped. The supply of the heat transfer gas to the bottom surface of the wafer W may also be stopped.

Then, the wafer W is raised by the lifter 107 and separated from the electrostatic chuck 104. During the separation, charge neutralization of the wafer W may be performed. The wafer W is unloaded from the chamber 100 by the transfer robot 70, and a series of wafer processing ends.

Wafer-less dry cleaning may be performed after the wafer W is unloaded from the chamber 100. That is, after the wafer W is unloaded from the chamber 100, plasma may be generated in the chamber 100 in a state where the wafer W is not placed on the wafer placing surface of the electrostatic chuck 104, and the electrostatic chuck 104 may be cleaned by the plasma.

Specifically, after the wafer W is unloaded, the cleaning gas may be supplied from the gas supply mechanism 140 to the processing space 100s via the upper electrode 102 in a state where the wafer W is not placed on the upper surface 104a of the central portion of the electrostatic chuck 104 that is the wafer placing surface. Further, as an example, the RF power HF for generating plasma may be supplied from the RF power supply unit 150 to the lower electrode 103, and accordingly, the gas is excited to generate plasma. The generated plasma can remove reaction products that adhere to, for example, a part between the central portion of the electrostatic chuck 104 and the edge ring E.

The RF power HF for generating plasma may be supplied to the upper electrode 102.

### <Method for Estimating Height of Edge Ring E>

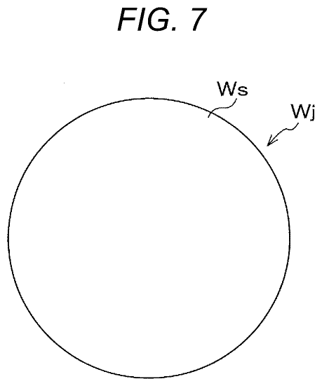

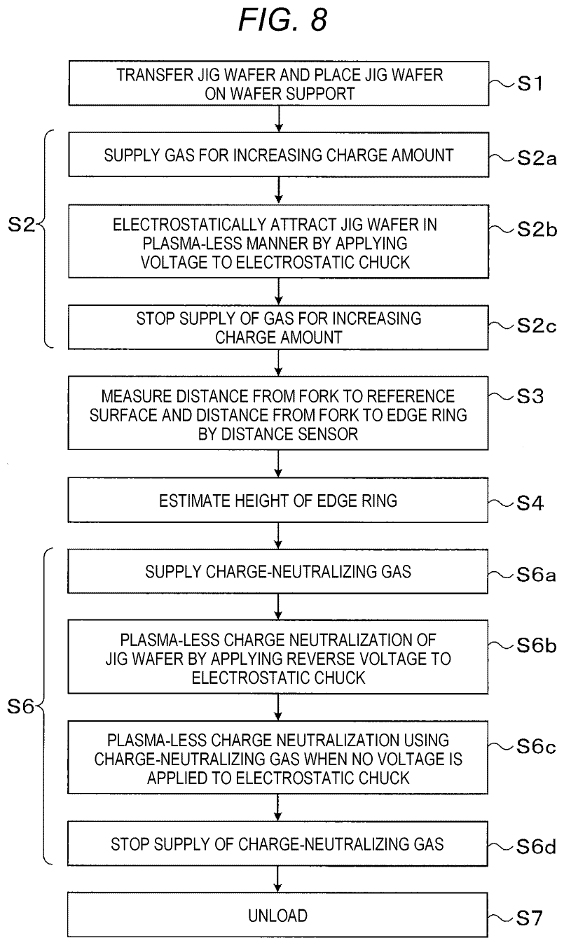

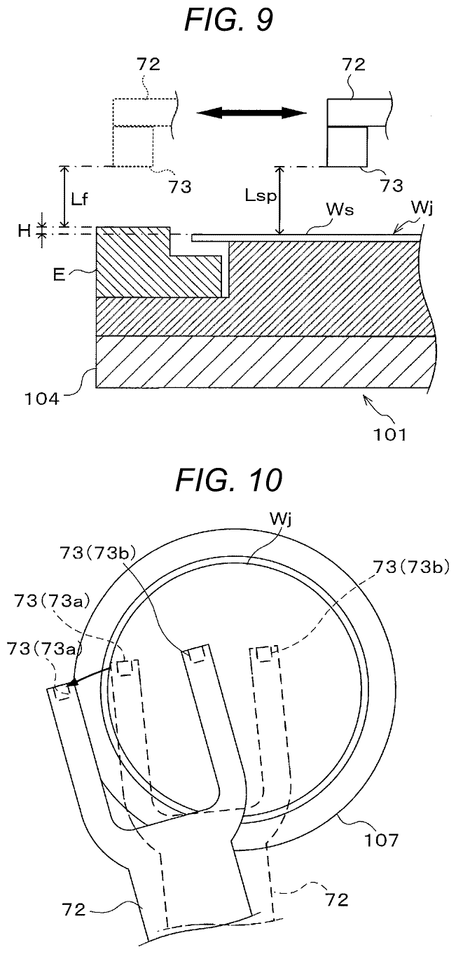

Next, an example of a method for estimating the height of the edge ring E placed on the electrostatic chuck 104 by the plasma processing system 1 will be described. FIG. 7 is a plan view of an example of a jig wafer serving as a jig substrate used for estimation of the height of the edge ring E. FIG. 8 is a flowchart showing an example of a method for estimating the height of the edge ring E. FIG. 9 is a view showing positions of the fork 72 and the distance sensor 73 with respect to the wafer support 101 when the height of the edge ring E is estimated. In the following steps, the exhaust system 160 continuously exhausts the inside of the chamber 100.

In the plasma processing system 1, the edge ring E placed on the electrostatic chuck 104 is worn by the above-described wafer processing using plasma. The degree of wear of the edge ring E can be determined from the height of the edge ring E placed on the electrostatic chuck 104. Therefore, in the plasma processing system 1, the control device 80 estimates the height of the edge ring E placed on the electrostatic chuck 104.

Further, in the plasma processing system 1, the jig wafer Wj shown in FIG. 7 is used when estimating the height of the edge ring E. The jig wafer Wj has the same shape in a plan view and material as the wafer W for which plasma processing is actually performed. The materials of the jig wafer Wj and the wafer W are, for example, silicon. The jig wafer Wj has a reference surface Ws serving as a reference of the height of the edge ring E, and the jig wafer Wj is placed on the electrostatic chuck 104 such that the reference surface Ws faces upward. Hereinafter, a surface of the jig wafer Wj facing upward in a state of being placed on the electrostatic chuck 104 is referred to as an upper surface.

In an example, the upper surface of the jig wafer Wj is formed flat on the entire surface, and the entire surface becomes the reference surface Ws.

The thickness of the jig wafer Wj may be the same as or different from the actual wafer W. Further, when the jig wafer Wj is not used, the jig wafer Wj is accommodated in, for example, the storage module 33.

### [Step S1]

In the plasma processing system 1, when the height of the edge ring E is to be estimated, for example, the jig wafer Wj is transferred into the chamber 100 by the transfer robot 70 and placed on the wafer support 101 by the elevation mechanism under the control of the control device 80, as shown in FIG. 8.

Specifically, for example, first, the jig wafer Wj in the storage module 33 is loaded into the chamber 100 of the processing module 60 to which the edge ring E that is a height measurement target is attached (hereinafter, referred to as the processing module 60 as a height measurement target) by the transfer device 40 and the transfer robot 70.

More specifically, for example, the jig wafer Wj in the storage module 33 is held by the transfer arm 41 of the transfer device 40 and loaded into the load-lock module 20. Next, the load-lock module 20 is sealed and decompressed. Thereafter, the inner space of the load-lock module 20 communicates with the inner space of the transfer module 50. Subsequently, the jig wafer Wj is held by the transfer arm 71 of the transfer robot 70. Further, the gate valve 62 corresponding to the processing module 60 as a measurement target is opened, and the transfer arm 71 holding the jig wafer Wj is inserted into the chamber 100 via a loading and unloading port (not shown). Then, the jig wafer Wj is transferred above the upper surface 104a of the central portion of the electrostatic chuck 104 by the transfer arm 71.

Next, the jig wafer Wj is transferred from the transfer robot 70 to the lifter 107.

Specifically, the lifter 107 is raised, and the jig wafer Wj is transferred from the transfer arm 71 to the lifter 107. Next, the transfer arm 71 is retracted from the chamber 100, and the gate valve 62 is closed.

Thereafter, the jig wafer Wj is lowered by the elevation mechanism that includes the lifter 107 and placed on the upper surface 104a (hereinafter, referred to as the wafer placing surface 104a) of the central portion of the electrostatic chuck 104.

Specifically, the lifter 107 is lowered until the upper end of the lifter 107 is accommodated in the insertion hole 115. Accordingly, the jig wafer Wj is placed on the wafer placing surface 104a.

### [Step S2]

Next, under the control of the control device 80, a predetermined voltage is applied to the electrostatic chuck 104 in a state where a predetermined gas is supplied into the chamber 100, and the jig wafer Wj is electrostatically attracted and held onto the wafer placing surface 104a in a plasma-less manner.

Specifically, for example, the following steps S2a to S2c are performed.

### [Step S2a]

In this step, first, the gas for increasing the charge amount is supplied into the chamber 100.

Specifically, an inert gas (such as a nitrogen gas or an argon gas) or an oxygen gas is supplied from the gas supply mechanism 140 into the chamber 100 via the upper electrode 102 as the gas for increasing the charge amount.

In step S2a, the pressure in the chamber 100 may be controlled to be 100 mTorr or more. However, when the gas for increasing the charge amount is supplied into the chamber 100, the pressure control in the chamber 100 may not be performed.

### [Step S2b]

After step S2a, a predetermined voltage is applied to the electrostatic chuck 104, and the jig wafer Wj is electrostatically attracted and held onto the wafer placing surface 104a in a plasma-less manner.

Specifically, in a state where the supply of the gas for increasing the charge amount is continued, and in a state where the radio-frequency power HF for generating plasma is not supplied from the RF power supply unit 150, a voltage of 1500 V to 6000 V is applied from the direct-current power supply 121a to the electrode 110 of the electrostatic chuck 104. Accordingly, the jig wafer Wj is electrostatically attracted and held onto the upper surface 104a of the central portion of the electrostatic chuck 104, which is the wafer placing surface, in a plasma-less manner. Further, at this time, since the supply of gas for increasing the charge amount is performed, an event that is electrically synonymous with the transfer of charges from the chamber 100 connected to the ground potential to the jig wafer Wj via the gas for increasing the charge amount occurs. Therefore, the charge amount of the jig wafer Wj increases and the electrostatic attraction force of the jig wafer Wj to the wafer placing surface 104a becomes stronger than when the gas for increasing the charge amount is not supplied.

### [Step S2c]

After step S2b, the supply of the predetermined gas is stopped.

Specifically, the supply of the gas for increasing the charge amount from the gas supply mechanism 140 into the chamber 100 via the upper electrode 102 is stopped in a state where the electrostatic adsorption of the jig wafer Wj is continued.

### [Step S3]

Thereafter, the fork 72 of the transfer robot 70 is located above the wafer support 101 under the control of the control device 80, and the distance sensor 73 measures a distance to the reference surface Ws of the jig wafer Wj placed on the wafer placing surface 104a, and a distance to the edge ring E attached to the wafer support 101.

Specifically, in a state where the electrostatic attraction of the jig wafer Wj is continued, the gate valve 62 is opened, and the fork 72 is moved to a position above the wafer support 101 on which the jig wafer Wj and the edge ring E are placed, as shown in FIG. 9.

Further, in a state where the electrostatic attraction of the jig wafer Wj is continued, the distance from the fork 72 (specifically, the distance sensor 73) located above the wafer support 101 to the reference surface Ws of the jig wafer Wj and the distance from the fork 72 (specifically, the distance sensor 73) to the edge ring E are measured by the distance sensor 73. Specifically, for example, the distance sensor 73 emits light for distance measurement to a predetermined reference position on the reference surface Ws of the jig wafer Wj, and the reflected light is received by the distance sensor 73. The reference position is provided, for example, at a peripheral end portion of the jig wafer Wj. Next, based on the light reception result, a distance Lsp from the fork 72 to the predetermined reference position on the reference surface Ws of the jig wafer Wj is calculated by the above-described unit controller. Similarly, the distance sensor 73 emits light for distance measurement to a predetermined measurement position of the edge ring E, and the reflected light is received by the distance sensor 73. The measurement position is provided, for example, at an inner peripheral end portion of the edge ring E, that is, a peripheral end portion of the edge ring E on the side of the jig wafer W. Next, a distance Lf from the fork 72 to the edge ring E is calculated by the unit controller based on the light reception result.

In the following descriptions, “the distance from the fork 72 to XX” may be abbreviated to “the distance to XX”.

Then, the fork 72 is retracted from the chamber 100, and the gate valve 62 is closed.

### [Step S4]

Next, the control device 80 calculates, i.e., estimates the height of the edge ring E based on the distance to the reference surface Ws and the distance to the edge ring E. For example, the control device 80 calculates a height H (specifically, the height from the reference surface Ws) of the edge ring E based on the following formula (X) using the distance Lsp and the distance Lf.

H=Lsp−Lf (X)

### [Step S5]

Thereafter, the application of the predetermined voltage to the electrostatic chuck 104 for electrostatic attraction of the jig wafer Wj is stopped under the control of the control device 80.

Specifically, the application of the voltage from the direct-current power supply 121a to the electrode 110 of the electrostatic chuck 104 is stopped.

### [Step S6]

Subsequently, the charge-neutralizing gas is supplied into the chamber 100, and the charges on jig wafer Wj placed on the wafer placing surface 104a are neutralized in a plasma-less manner.

Specifically, for example, the following steps S6a to S6d are performed.

### [Step S6a]

In this step, first, a charge-neutralizing gas is supplied into the chamber 100.

Specifically, an inert gas (such as a nitrogen gas or an argon gas) or an oxygen gas is supplied from the gas supply mechanism 140 into the chamber 100 via the upper electrode 102 as a charge-neutralizing gas. The charge-neutralizing gas may be the same as or different from the gas for increasing the charge amount.

In step S6a, the pressure in the chamber 100 may be controlled to be 700 mTorr±100 m Torr.

### [Step S6b]

After step S6a, a voltage having a predetermined magnitude with a polarity opposite to that in step S2b is applied to the electrostatic chuck 104, and the charges on the jig wafer Wj placed on the wafer placing surface 104a are neutralized in a plasma-less manner.

Specifically, in a state where the supply of the charge-neutralizing gas into the chamber 100 is continued, and in a state where the radio-frequency power HF for generating plasma is not supplied from the RF power supply unit 150, a voltage of 100 V to 1500 V having a polarity opposite to that in step S2b is applied from the direct-current power supply 121a to the electrode 110 of the electrostatic chuck 104. By such application of the reverse polarity voltage, an event electrically synonymous with the occurrence of the charge of the jig wafer Wj before the application flowing to the ground potential to which the chamber 100 is connected via the gas in the chamber 100 occurs, and the occurrence of the event is accelerated, so that the charges on the jig wafer Wj can be neutralized in a plasma-less manner.

The application time of the voltage of the reverse polarity is, for example, 5 seconds, and when this application time is exceeded, the application is stopped.

### [Step S6c]

After step S6b, the charge-neutralizing gas is supplied into the chamber 100 in a state where no voltage is applied to the electrostatic chuck 104, and the charges on the jig wafer Wj placed on the wafer placing surface 104a are further neutralized.

Specifically, after steps S6a and S6b, the supply of the charge-neutralizing gas into the chamber 100 is continued for a predetermined time in a state where no voltage is applied to the electrostatic chuck 104. Accordingly, an event electrically synonymous with the occurrence of the charge of the jig wafer Wj flowing to the ground potential to which the chamber 100 is connected via the charge-neutralizing gas in the chamber 100 occurs, and therefore, the charges on the jig wafer Wj can be further neutralized in a plasma-less manner. The supply time of the charge-neutralizing gas in step S6b is, for example, 30 seconds to 60 seconds.

Further, in step 6c, the pressure in the chamber 100 may be controlled as in step S6a.

This step S6c may be omitted.

### [Step S6d]

After step S6c, the supply of the charge-neutralizing gas is stopped.

Specifically, the supply of the charge-neutralizing gas from the gas supply mechanism 140 into the chamber 100 via the upper electrode 102 is stopped.

### [Step S7]

Then, under the control of the control device 80, the jig wafer Wj is separated from the wafer support 101 by the elevation mechanism and unloaded from the chamber 100 by the transfer robot 70.

Specifically, the jig wafer Wj is raised by the elevation mechanism including the lifter 107, and separated from the wafer placing surface 104a.

More specifically, the lifter 107 is raised until the upper end of the lifter 107 protrudes from the wafer placing surface 104a, and accordingly, the jig wafer Wj is separated from the wafer placing surface 104a. After the separation, the jig wafer Wj is raised to a predetermined height by the rise of the lifter 107.

Next, the jig wafer Wj is transferred from the lifter 107 to the transfer robot 70.

Specifically, for example, the gate valve 62 is opened, and the transfer arm 71 of the transfer robot 70 is inserted into the chamber 100. Next, the transfer arm 71 is moved between the electrostatic chuck 104 and the jig wafer Wj supported by the lifter 107. Subsequently, the lifter 107 is lowered, and the jig wafer Wj is transferred to the transfer arm 71.

Thereafter, the jig wafer Wj in the chamber 100 returns to the storage module 33 by the transfer robot 70 and the transfer device 40.

Specifically, for example, the transfer arm 71 is extracted from the chamber 100, and the jig wafer Wj is unloaded from the chamber 100 to the transfer module 50. Next, the gate valve 62 is closed. Thereafter, the inside of the transfer module 50 communicates with the inside of the decompressed load-lock module 20. Subsequently, the jig wafer Wj is loaded into the load-lock module 20. Next, the load-lock module 20 is sealed and returned to the atmospheric pressure. Thereafter, the jig wafer Wj in the load-lock module 20 is held by the transfer arm 41 of the transfer device 40 and returns to the storage module 33.

With the above procedure, the flow of estimating the height of the edge ring E placed on the electrostatic chuck 104 by the plasma processing system 1 is completed.

The estimation of the height of the edge ring E placed on the electrostatic chuck 104 by the plasma processing system 1 is performed, for example, every time a predetermined time elapses or every time a predetermined number of wafers W are processed.

### Effects of Present Embodiment

As described above, in the present embodiment, when the height of the edge ring E attached to the wafer support 101 is to be estimated, the jig wafer Wj having the reference surface Ws with the height of the edge ring E is placed on the wafer placing surface 104a of the wafer support 101. The control device 80 estimates the height of the edge ring E based on the measurement results of the distance to the reference surface Ws of the jig wafer Wj on the wafer placing surface 104a and the distance to the edge ring E by the distance sensor 73 provided on the fork 72 of the transfer robot 70. Therefore, even if the wafer placing surface 104a is provided with the plurality of protruding portions 104c as shown in FIG. 6, the height of the edge ring E can be accurately estimated. Further, the distance to the edge ring E is estimated using the measurement result of the distance to the reference surface Ws, and therefore, the height of the edge ring E can be accurately estimated even when the fork 72 sags by its own weight due to a temporal change or the like.

Further, in the present embodiment, a predetermined voltage is applied to the electrostatic chuck 104 in a state where the gas for increasing the charge amount is supplied into the chamber 100, and the jig wafer Wj is electrostatically attracted and held onto the wafer placing surface 104a. Therefore, it is possible to increase the charge amount of the jig wafer Wj during the electrostatic attraction to the wafer placing surface 104a, compared with the case where the gas for increasing the charge amount is not supplied into the chamber 100 when the predetermined voltage is applied to the electrostatic chuck 104. Hereinafter, this point will be described.

The wafer placing surface 104a may be charged before the jig wafer Wj is placed. Further, the charge amount of the wafer placing surface 104a before the jig wafer Wj is placed may vary depending on whether the above-described wafer-less cleaning is performed, the details of the wafer-less cleaning, or the like. When the charge amount varies, the electrostatic attraction force of the jig wafer Wj to the wafer placing surface 104a is also different. The strength of this electrostatic attraction force affects the height of the reference surface Ws of the jig wafer Wj electrostatically attracted to the wafer placing surface 104a.

In contrast, in the present embodiment, the charge amount of the jig wafer Wj during the electrostatic attraction to the wafer placing surface 104a can be increased as described above, and therefore, it is possible to prevent the influence of the difference in the charge amount of the wafer placing surface 104a before the jig wafer Wj is placed on the wafer placing surface 104a on the electrostatic attraction force of the jig wafer Wj to the wafer placing surface 104a. Therefore, it is possible to prevent the height of the reference surface Ws during the measurement of the distance to the reference surface Ws of the jig wafer Wj from being affected by the difference in the charge amount of the wafer placing surface 104a before the jig wafer Wj is placed. Therefore, it is possible to prevent the estimation result of the height of the edge ring E from being affected by the difference in the charge amount of the wafer placing surface 104a before the jig wafer Wj is placed.

Further, in the present embodiment, the processing of increasing the charge amount of the jig wafer Wj on the wafer placing surface 104a in step S2 is performed in a plasma-less manner. Therefore, the reference surface Ws of the jig wafer Wj is not damaged by the plasma due to the process of increasing the charge amount of the jig wafer Wj. Therefore, it is possible to prevent the deterioration in the accuracy of the estimation result of the height of the edge ring E based on the measurement result of the height of the reference surface Ws due to the processing of increasing the charge amount of the jig wafer Wj.

Further, in the present embodiment, in a state where the charge neutralizing gas is supplied into the chamber 100, a voltage having a polarity opposite to that when the jig wafer Wj is attracted to the electrostatic chuck 104 is applied to the electrostatic chuck 104, so that the charges on the jig wafer Wj on the wafer placing surface 104a are neutralized.

Therefore, even if the processing of increasing the charge amount of the jig wafer Wj is performed as described above, and the electrostatic attraction force to the wafer placing surface 104a of the jig wafer Wj is high, the electrostatic attraction force is weakened by the charge neutralization. Therefore, it is possible to prevent the jig wafer Wj, which has been electrostatically attracted to the wafer placing surface 104a, from becoming unable to be removed from the wafer placing surface 104a. Further, when the jig wafer Wj, which has been electrostatically attracted to the wafer placing surface 104a, is raised by the elevation mechanism including the lifter 107 and separated from the wafer placing surface 104a, the jig wafer Wj can be prevented from being damaged. In other words, the jig wafer Wj can be stably used during the estimation of the height of the edge ring E. Further, the lifter 107 can be prevented from being damaged when the jig wafer Wj, which has been electrostatically attracted to the wafer placing surface 104a, is separated from the wafer placing surface 104a.

As described above, the magnitude of the reverse voltage that is applied to the electrostatic chuck 104 during the charge neutralization is 100 V to 1500 V. When the magnitude of the reverse voltage is set to 100 V or more, the jig wafer Wj can be more reliably prevented from becoming unable to be separated from the wafer placing surface 104a. Further, when the magnitude of the reverse voltage is set to 1500 V or lower, it is possible to prevent the jig wafer Wj from being charged to the polarity opposite to that before the start of the charge neutralization and being unable to be separated from the wafer placing surface 104a.

Further, the charge neutralization processing of the jig wafer Wj is performed in a plasma-less manner. Therefore, the reference surface Ws of the jig wafer Wj to be repeatedly used is not damaged by the plasma due to the charge neutralization processing of the jig wafer Wj. Therefore, it is possible to prevent the deterioration in the accuracy of the estimation result of the height of the edge ring E based on the measurement result of the height of the reference surface Ws due to the charge neutralization processing of the jig wafer Wj.

Further, in the present embodiment, before the jig wafer Wj is separated from the wafer placing surface 104a, the charge-neutralizing gas is supplied into the chamber 100 in a state where no voltage is applied to the electrostatic chuck 104, and the charges of the jig wafer Wj placed on the wafer placing surface 104a are neutralized in a plasma-less manner. Therefore, it is possible to more reliably prevent the damage to the lifter 107 or the jig wafer Wj when the jig wafer Wj is separated from the wafer placing surface 104a by the elevation mechanism including the lifter 107 after the charge neutralization, and to prevent the reference surface Ws of the jig wafer Wj from being damaged by the plasma by the charging neutralization processing.

The present inventors have conducted a test employing a method for separating the jig wafer Wj from the wafer placing surface 104a according to the present disclosure, and have found the following points. That is, according to the present separation method, even when the voltage applied to the electrostatic chuck 104 for electrostatically attracting the jig wafer Wj is as high as 3000 V, it is found that the jig wafer Wj can be separated from the wafer support 101 without damage to the jig wafer Wj or the like, and that the jig wafer Wj does not significantly move in the horizontal direction during the separation. Further, it is found that these points do not depend on the temperature of the chamber 100.

Further, in the present embodiment, the control device 80 estimates the height of the edge ring E based on the measurement results of the distance to the predetermined reference position on the reference surface Ws of the jig wafer Wj on the wafer placing surface 104a and the distance to the predetermined measurement position of the edge ring E obtained by the distance sensor 73 provided on the fork 72 of the transfer robot 70. The reference position is provided at a peripheral end portion of the jig wafer Wj, the measurement position is a peripheral end portion of the edge ring E on the side of the jig wafer Wj, and the reference position and the measurement position are close to each other. Therefore, even if the sag that depends on the distance the fork 72 enters the chamber 100 occurs, the measurement error caused by the sag can be prevented, and the height of the edge ring E can be more accurately estimated.

### Another Example 1 of Steps S3 and S4

FIG. 10 is a view illustrating another example of the step of measuring the height of the reference surface Ws of the jig wafer Wj and the height of the edge ring E in step S3, and the step of estimating the height of the edge ring E by the control device 80 in step S4.

When measuring the distance to the edge ring E in step S3, the fork 72 may be moved to move the distance sensor 73a in a predetermined direction under the control of the control device 80 as shown in FIG. 10. The predetermined direction refers to a direction crossing the edge ring E in a plan view, and refers to a direction intersecting a direction in which the fork 72 is inserted into and extracted from the chamber 100 (the up-down direction in FIG. 10).

A method of moving the distance sensor 73a in the direction crossing the edge ring E in a plan view may be a method of turning the fork 72 around a base end of the fork 72 provided with the distance sensor 73a, or a method of turning the transfer arm 71 around the base end of the transfer arm 71.

As described above, the distance Lf to the edge ring E may be continuously measured by the distance sensor 73a while the distance sensor 73a is moved in the direction crossing the edge ring E in a plan view. In step S4, the control device 80 may estimate the height distribution or profile of the edge ring E in the cross direction, based on, for example, the continuous measurement results of the distance Lsp to the reference point of the reference surface Ws of the jig wafer Wj and the distance Lf to the edge ring E. Specifically, the control device 80 may calculate the height H of the edge ring E regarding each measurement point of the distance Lf to the edge ring E based on the above formula (X), and may create a height distribution of the edge ring E in the cross direction based on each calculation result and positional information of each measurement point. The positional information of each measurement point can be calculated based on angles and dimensions of constituent members of the transfer arm 71 when the distance Lf is measured.

Further, in step S4, the control device 80 may estimate the height of the edge ring E based on an average value of the continuous measurement results of the distance Lsp to the reference point of the reference surface Ws of the jig wafer Wj and the distance Lf to the edge ring E.

### Another Example 2 of Steps S3 and S4

When the fork 72 is moved to move the distance sensor 73a in the cross direction as in the other example 1 described above, the fork 72 may vibrate during the movement.

In the case where the fork 72 vibrates, when the profile of the height of the edge ring E is estimated as in the other example 1 described above, the profile may be a profile in which a vibration component of the fork 72 is superimposed on the actual profile of the height of the edge ring E.

In order to eliminate the influence of the vibration component of the fork 72, the following may be adopted.

That is, in step S3, as shown in FIG. 10, the distance to the edge ring E may be continuously measured by the one distance sensor 73a while the fork 72 is moved to move the one distance sensor 73a in a direction crossing the edge ring E in a plan view. Further, in parallel with this measurement, the distance to the reference surface Ws of the jig wafer Wj may be continuously measured by the other distance sensor 73b. In step S4, the control device 80 may estimate a profile D of the height of the edge ring E in the cross direction based on the measurement results of a distance Lft to the edge ring E and the measurement results of a distance Lst to the reference surface Ws at each time point during the measurements performed by the distance sensors 73a and 73b. Specifically, the control device 80 may calculate a height Ht of the edge ring E based on the difference between the distance Lft and the distance Lst at each time point during the measurements performed by the distance sensor 73a and the distance sensor 73b, i.e., based on the formula (Y) below.

Lst−Lft=Ht (Y)

The control device 80 may create a profile of the height in the cross direction of the edge ring E based on the calculation results of the height Ht and the positional information of the measurement point by the distance sensor 73a for each time point during the measurements performed by the distance sensor 73a and the distance sensor 73b.

The profile obtained in this way eliminates the influence of a vibration component

D2 of the fork 72.

Further, the profile obtained in this way is obtained by eliminating the influence of the inclination of the fork 72 with respect to the wafer support 101.

### Another Example 3 of Steps S3 and S4

Further, when measuring the distance to the edge ring E in step S3, not only the distance sensor 73a moves leftward in a plan view to move the fork 72 to cross the edge ring E, but also the distance sensor 73b may move rightward in a plan view to move the fork 72 to cross the edge ring E. In the present specification, “left” and “right” are based on the loading and unloading port of the chamber 100. Further, while the distance sensor 73a is moved leftward, the distance Lsp to a reference point on the left side of the reference surface of the jig wafer Wj may be measured by the distance sensor 73a, and the distance Lf to the edge ring E may be continuously measured by the distance sensor 73a regarding the left side of the edge ring E. In addition, while the distance sensor 73b is moved rightward, the distance sensor 73b may measure the distance to the reference point on the right side of the reference surface of the jig wafer Wj, and the distance Lf to the edge ring E may be continuously measured by the distance sensor 73a regarding the right side of the edge ring E.

In step S4, for example, the control device 80 may estimate a profile of the height of the left side of the edge ring E in the cross direction based on the continuous measurement results of the distance Lsp to the reference point on the left side of the reference surface of the jig wafer Wj and the distance Lf to the edge ring E on the left side of the edge ring E. In step S4, for example, the control device 80 may estimate a profile of the height of the right side of the edge ring E in the cross direction based on the continuous measurement results of the distance Lsp to the reference point on the right side of the reference surface of the jig wafer Wj and the distance Lf to the edge ring E on the right side of the edge ring E. Further, the control device 80 may generate a representative profile of the height of the edge ring E by averaging the estimation results of the heights of the corresponding positions using the profile of the height of the left side of the edge ring E and the profile of the height of the right side of the edge ring E.

In step S4, the control device 80 may estimate the height of the left side of the edge ring E based on an average value of the continuous measurement results of the distance Lsp to the reference point on the left side of the reference surface of the jig wafer Wj and the distance Lf to the edge ring E on the left side of the edge ring E. In step S4, the control device 80 may estimate the height of the right side of the edge ring E based on an average value of the continuous measurement results of the distance Lsp to the reference point on the right side of the reference surface of the jig wafer Wj and the distance Lf to the edge ring E on the right side of the edge ring E. Further, the control device 80 may calculate an average value of the height of the left side of the edge ring E and the height of the right side of the edge ring E, and use the calculation result as the representative height of the edge ring E.

### Another Example 4 of step S4

In step S4, the control device 80 may correct the estimation results of the height of the edge ring E based on the distance Lsp to the reference point on the reference surface Ws of the jig wafer Wj measured by the distance sensor 73 and a design value of the distance

Lsp. Accordingly, when the fork 72 sags by its own weight due to a temporal change or the like, the influence of the sag can be eliminated from the estimation result of the height of the edge ring E. The design value of the distance Lsp is stored in advance in a storage unit (not shown).

### Another Example of Jig Wafer

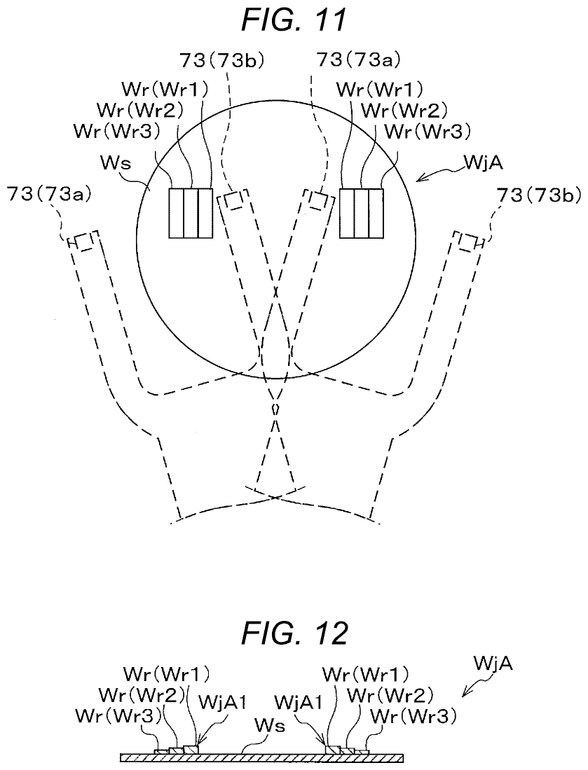

FIGS. 11 and 12 are respectively a plan view and a cross-sectional view schematically showing another example of the jig wafer.

As shown in FIGS. 11 and 12, a jig wafer WjA has a plurality of correction surfaces Wr spaced apart from the reference surface Ws by a predetermined distance in the height direction, and the plurality of correction surfaces Wr are different from each other in distance from the reference surface Ws in the height direction.

In the illustrated example, correction surfaces Wr1 to Wr3 are provided as the correction surfaces Wr for each of the distance sensor 73a and the distance sensor 73b. The distances from the correction surfaces Wr1 to Wr3 to the reference surface Ws are accurately defined in advance. In the jig wafer WjA in the illustrated example, a member WJA 1 having stepped surfaces with different heights from one another is provided on the reference surface Ws, and each stepped surface forms the correction surfaces Wr1 to Wr3. However, unlike the present example, grooves having different recess depths from the reference surface Ws may be formed in the jig wafer WjA, and the bottom surfaces of the grooves may form the correction surfaces Wr1 to Wr3.

The distances from the reference surface Ws to the correction surfaces Wr1, Wr2, and Wr3 are, for example, 100 μm, 50 μm, and 25 μm, respectively.

Further, for example, the member WJA 1 of the jig wafer WjA has the same material as the wafer W subjected to plasma processing, and is bonded to the reference surface Ws for use.

In the case where the jig wafer WjA is used, when the distance to the reference surface Ws and the distance to the edge ring E are measured by the distance sensor 73, the distances to the plurality of correction surfaces Wr are also measured. For example, the distance sensor 73 measures the distance to the correction surface Wr1 and the distance to the correction surface Wr2.

Then, the control device 80 corrects the measurement results obtained by the distance sensor 73 based on the measurement results of the distances to the plurality of correction surfaces Wr. Specifically, for example, the control device 80 obtains a difference Df between the distance to the correction surface Wr1 and the distance to the correction surface Wr2 detected by the distance sensor 73. Then, the control device 80 corrects the measurement results obtained by the distance sensor 73 such that the difference Df approaches a design value of the difference Df. Accordingly, the control device 80 can more accurately acquire the distance to the reference surface Ws and the distance to the edge ring E, and as a result, can more accurately estimate the height of the edge ring E. The design value of the difference Df is stored in advance in the storage unit (not shown).

When the jig wafer WjA is used to estimate the height of the edge ring E as in the other example 2 of steps S3 and S4 described above, the correction surface Wr is provided in the following regions of the jig wafer WjA. That is, the correction surface Wr is provided in a region on the jig wafer WjA where a continuous measurement of the distance to the reference surface Ws performed by the distance sensors 73a and 73b when the fork 72 is moved is not hindered.

### <Checking Test>

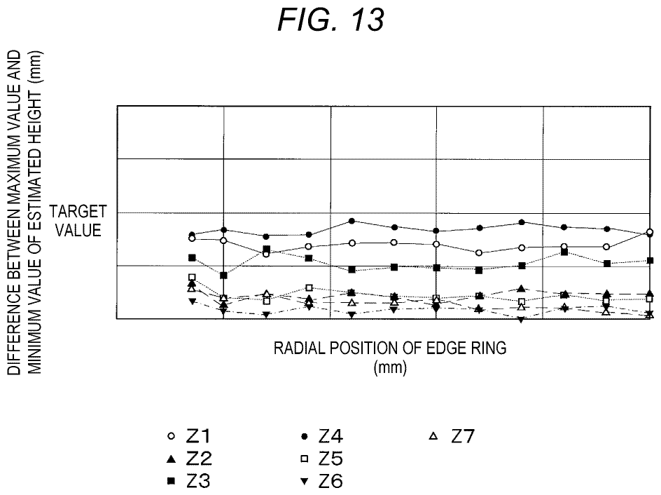

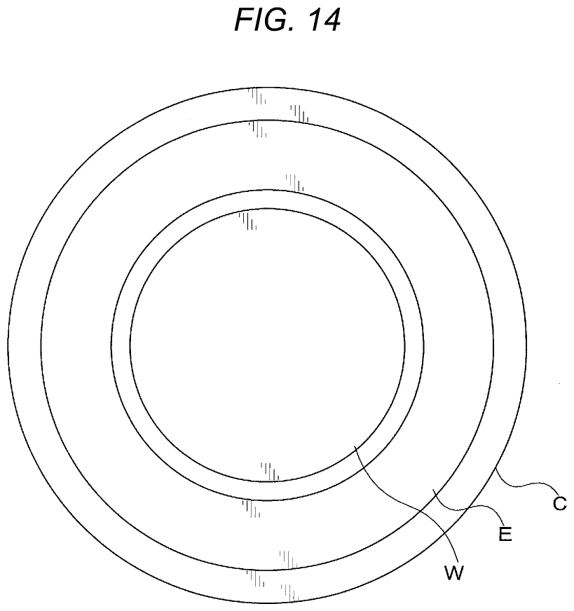

FIG. 13 is a diagram showing results of a test performed to check repeatability of an estimation result of the height of the edge ring E according to the technique of the present disclosure. In the checking test, for the processing module 60 where plasma processing of the edge ring E is repeatedly performed, the height of the edge ring E was estimated at different timings between plasma processing using the method including the above-described steps S1 to S7. The timing when the height of the edge ring E is estimated is timing when the total time of the plasma processing performed on the wafer W in the corresponding processing module 60 is Z1 to Z7 (Z1 to Z7 are different times of 0 hour or longer and 500 hours or shorter). Further, in the present checking test, the other example 2 described above was adopted as steps S3 and S4, and the jig wafer WjA shown in FIGS. 11 and 12 was used. Further, in the present checking test, the same jig wafer WjA was used across different estimation timings, i.e., one jig wafer WjA was repeatedly used. Further, at each estimation timing, the height of the edge ring E was estimated three times according to the method including steps S1 to S7. In FIG. 13, a horizontal axis represents a radial position of the edge ring E, and a vertical axis represents a repetition accuracy of estimation results of the height of the edge ring E at each estimation timing, and specifically represents a difference between the maximum value and the minimum value of the estimated height of the edge ring E at each estimation timing. One division on the vertical axis corresponds to 0.005 m.

As shown in FIG. 13, the difference between the maximum value and the minimum value of the estimated height of the edge ring E is equal to or less than the target value, regardless of the estimation timing and the radial position of the edge ring E. That is, according to the present disclosure, the height of the edge ring E worn by plasma can be estimated with high accuracy over a long period of time without replacing the jig wafer Wj.

### <Other Modifications>

One of the correction surfaces Wr of the jig wafer WjA may be the reference surface Ws for the height of the edge ring E.

Further, the amount of wear of the edge ring E can be determined based on the estimation results of the height of the edge ring E. Therefore, when the amount of wear of the edge ring E exceeds a threshold value, that is, when the height of the edge ring E falls below the threshold value, the edge ring E may be replaced, or a sheath shape on the edge ring E side may be changed by applying a voltage to the edge ring E.

To replace the edge ring E, the edge ring E having an estimated height lower than the threshold value is separated from the wafer support 101 by the elevation mechanism including the lifter 108, and unloaded from the chamber 100 by the transfer robot 70 under the control of the control device 80 without the chamber 100 being exposed to the atmosphere.

Specifically, the edge ring E is raised by the elevation mechanism including the lifter 107, and is separated from the upper surface (hereinafter, referred to as a ring placing surface) 104b of the peripheral portion of the electrostatic chuck 104.

More specifically, the lifter 108 is raised until the upper end of the lifter 108 protrudes from the ring placing surface 104b, and thus the edge ring E is separated from the ring placing surface 104b. After the separation, the edge ring E is lifted to a predetermined height by the rise of the lifter 108.

Next, the edge ring E is transferred from the lifter 108 to the transfer robot 70.

Specifically, for example, the gate valve 62 is opened, and the transfer arm 71 of the transfer robot 70 is inserted into the chamber 100. Next, the transfer arm 71 is moved between the edge ring E supported by the lifter 108 and the electrostatic chuck 104. Subsequently, the lifter 108 is lowered, and the edge ring E is transferred to the transfer arm 71.

Thereafter, the edge ring E in the chamber 100 is transferred into the accommodation module 61 by the transfer robot 70.

Specifically, for example, the transfer arm 71 is extracted from the chamber 100, and the edge ring E is unloaded from the chamber 100 to the transfer module 50. Next, the gate valve 62 is closed, and the gate valve 63 is opened. Thereafter, the edge ring E is accommodated in the accommodation module 61.

Then, under the control of the control device 80, the replacement edge ring E is transferred into the chamber 100 by the transfer robot 70 and placed on the wafer support 101 by the elevation mechanism including the lifter 180.

Specifically, for example, first, the replacement edge ring E in the accommodation module 61 is held by the transfer arm 71 of the transfer robot 70. Next, the transfer arm 71 holding the edge ring E is inserted into the corresponding chamber 100 via a loading and unloading port (not shown). Then, the edge ring E is transferred above the ring placing surface 104b by the transfer arm 71.

Next, the edge ring E is transferred from the transfer robot 70 to the lifter 108.

Specifically, the lifter 108 is raised, and the edge ring E is transferred from the transfer arm 71 to the lifter 108. Next, the transfer arm 71 is retracted from the chamber 100, and the gate valve 62 is closed.

Thereafter, the edge ring E is lowered by the elevation mechanism including the lifter 107, and is placed on the ring placing surface 104b.

Specifically, the lifter 108 is lowered until the upper end of the lifter 108 is accommodated in the insertion hole 119. Accordingly, the edge ring E is placed on the ring placing surface 104b.

The replacement edge ring E may be a new one, or may be a used one with only a small amount of wear.

In the above example, the jig wafer Wj is stored in the storage module 33. However, the jig wafer Wj may be stored in the hoop 31, or may be stored in the accommodation module 61.

Further, in the above example, the accommodation module 61 serving as a member storage for storing the edge ring E is connected to the transfer module 50. However, the member storage may be connected to one side surface forming the long side or one side surface forming the short side of the housing of the loader module 30. Further, the hoop 31 placed in the load port 32 may be a member storage. In these cases, the transfer device 40 may be configured to transfer the edge ring E for replacement.

As shown in FIG. 14, in addition to the edge ring E, a cover ring C disposed to cover the outer surface of the edge ring E may be attached to the wafer support as an annular member. The technique of the present disclosure can also be applied to the estimation of the height of the cover ring C attached to the wafer support.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein.

The effects described herein are merely illustrative or exemplary, and are not limited. In other words, the technique according to the present disclosure may have other effects apparent to those skilled in the art from the description herein, in addition to or in place of the effects described above.

The following configuration examples also fall within the technical scope of the present disclosure.
(1) A plasma processing system including:
a plasma processing apparatus,
a reduced-pressure transfer apparatus connected to the plasma processing apparatus and including a transfer robot configured to transfer a substrate, and
a control device, in which
the plasma processing apparatus includes
   a processing container configured to be depressurized,
   a substrate support which is provided in the processing container and includes a substrate placing surface and an electrostatic chuck configured to electrostatically attract the substrate to the substrate placing surface, and to which an annular member is attached so as to surround the substrate placing surface,
   an elevation mechanism configured to raise and lower the substrate relative to the substrate placing surface, and
   a gas supply configured to supply a gas into the processing container, the transfer robot includes
   a holder configured to hold the substrate to be transferred, and
   a distance sensor provided on the holder and configured to measure a distance from the holder, and
the control device executes
   (A) loading a jig substrate having a reference surface serving as a reference of a height of the annular member into the processing container by the transfer robot and placing the jig substrate on the substrate support by the elevation mechanism,
   (B) applying a voltage to the electrostatic chuck in a state where the gas is supplied into the processing container and attracting the jig substrate to the substrate placing surface in a plasma-less manner,
   (C) positioning the holder of the transfer robot above the substrate support and measuring, by the distance sensor, a distance to the reference surface of the jig substrate placed on the substrate placing surface and a distance to the annular member attached to the substrate support, and
   (D) estimating the height of the annular member based on measurement results of the distance to the reference surface and the distance to the annular member.
(2) The plasma processing system according to (1), in which
the control device further executes
   (E) supplying the gas into the processing container, and neutralizing charges of the jig substrate placed on the substrate placing surface in a plasma-less manner, and
   (F) separating the jig substrate from the substrate support by the elevation mechanism after the (E), and unloading the jig substrate from the processing container by the transfer robot, and
   the (E) includes (G) supplying the gas into the processing container in a state where a voltage having a polarity opposite to a polarity of the voltage during the (B) is applied to the electrostatic chuck, and neutralizing the charges of the jig substrate placed on the substrate placing surface in a plasma-less manner.
(3) The plasma processing system according to (2), in which
the (E) includes (H) supplying the gas into the processing container in a state where no voltage is applied to the electrostatic chuck, and neutralizing the charges of the jig substrate placed on the substrate placing surface in a plasma-less manner.
(4) The plasma processing system according to (3), in which
the (H) is executed after the (G).
(5) The plasma processing system according to any one of (1) to (4), in which
the gas is an inert gas or an oxygen gas.
(6) The plasma processing system according to any one of (1) to (5), in which
the plasma processing apparatus further includes another elevation mechanism configured to raise and lower the annular member relative to the substrate support,
the transfer robot is also configured to transfer the annular member, and
the control device further executes
   (I) separating the annular member from the substrate support by the other elevation mechanism when the height of the annular member estimated in the (D) is lower than a threshold value, and unloading the annular member from the processing container by the transfer robot, and
   (J) loading an annular member for replacement into the processing container by the transfer robot and placing the annular member for replacement on the substrate support by the elevation mechanism after the (I).
(7) The plasma processing system according to any one of (1) to (6), further including:
a member storage configured to store the annular member, in which
the member storage is connected to the reduced-pressure transfer apparatus.
(8) The plasma processing system according to any one of (1) to (6), further including:
an atmospheric pressure transfer apparatus which is connected to the reduced-pressure transfer apparatus via a load-lock apparatus configured to switch an inner space between an atmospheric pressure atmosphere and a pressure-reduced atmosphere, and includes a transfer device that operates under an atmospheric pressure atmosphere and that transfers the substrate, and
a member storage connected to the atmospheric pressure transfer apparatus and configured to store the annular member.
(9) The plasma processing system according to (7) or (8), in which
the jig substrate is stored in the member storage.
(10) The plasma processing system according to any one of (1) to (9), further including:
an atmospheric section which is connected to the reduced-pressure transfer apparatus via the load-lock apparatus configured to switch an inner space between an atmospheric pressure atmosphere and a pressure-reduced atmosphere, and operates under an atmospheric pressure atmosphere, in which
the jig substrate is stored in a storage container placed in the atmospheric section and configured to store substrates, or stored in a substrate storage provided in the atmospheric section separately from the storage container.
(11) The plasma processing system according to any one of (1) to (10), in which
the annular member is an edge ring disposed to be adjacent to the substrate on the substrate support, or a cover ring disposed to cover an outer surface of the edge ring.
(12) The plasma processing system according to any one of (1) to (11), in which
in the (C), the holder is moved above the substrate support such that the distance sensor crosses the annular member in a plan view, and the distance sensor measures the distance to the reference surface of the jig substrate placed on the substrate placing surface, and continuously measures the distance to the annular member attached to the substrate support, and
in the (D), a profile of the height of the annular member in the cross direction is estimated based on a measurement result of the distance to the reference surface and a measurement result of the distance to the annular member in the (C).
(13) A method for estimating a height of an annular member in a plasma processing system which includes a plasma processing apparatus, and a reduced-pressure transfer apparatus connected to the plasma processing apparatus and including a transfer robot configured to transfer a substrate, the plasma processing apparatus including a processing container configured to be depressurized, a substrate support which is provided in the processing container and includes a substrate placing surface and an electrostatic chuck configured to electrostatically attract the substrate to the substrate placing surface, and to which the annular member is attached so as to surround the substrate placing surface, and an elevation mechanism configured to raise and lower the substrate relative to the substrate placing surface, the transfer robot including a holder configured to hold the substrate to be transferred, and a distance sensor provided on the holder and configured to measure a distance from the holder, the method comprising:
(A) loading a jig substrate having a reference surface serving as a reference of the height of the annular member into the processing container by the transfer robot and placing the jig substrate on the substrate support by the elevation mechanism,
(B) applying a voltage to the electrostatic chuck in a state where a gas is supplied into the processing container and attracting the jig substrate to the substrate placing surface in a plasma-less manner,
(C) positioning the holder of the transfer robot above the substrate support and measuring, by the distance sensor, a distance to the reference surface of the jig substrate placed on the substrate placing surface and a distance to the annular member attached to the substrate support, and
(D) estimating the height of the annular member based on measurement results of the distance to the reference surface and the distance to the annular member.

1. A plasma processing system comprising:
a plasma processing apparatus,
a reduced-pressure transfer apparatus connected to the plasma processing apparatus and including a transfer robot configured to transfer a substrate, and
a control circuitry, wherein
the plasma processing apparatus includes:
a processing container configured to be depressurized;
a substrate support which is provided in the processing container and includes a substrate placing surface and an electrostatic chuck configured to electrostatically attract the substrate to the substrate placing surface, and to which an annular member is attached so as to surround the substrate placing surface;
an elevation mechanism configured to raise and lower the substrate relative to the substrate placing surface; and
a gas supply configured to supply a gas into the processing container,
the transfer robot includes:
a holder configured to hold the substrate to be transferred, and
a distance sensor provided on the holder and configured to measure a distance from the holder, and
the control circuitry executes:
(A) loading a jig substrate having a reference surface serving as a reference of a height of the annular member into the processing container by the transfer robot and placing the jig substrate on the substrate support by the elevation mechanism,
(B) applying a voltage to the electrostatic chuck in a state where the gas is supplied into the processing container and attracting the jig substrate to the substrate placing surface in a plasma-less manner,
(C) positioning the holder of the transfer robot above the substrate support and measuring, by the distance sensor, a distance to the reference surface of the jig substrate placed on the substrate placing surface and a distance to the annular member attached to the substrate support, and
(D) estimating the height of the annular member based on measurement results of the distance to the reference surface and the distance to the annular member.

2. The plasma processing system according to claim 1, wherein
the control circuitry further executes:
(E) supplying the gas into the processing container, and neutralizing charges of the jig substrate placed on the substrate placing surface in a plasma-less manner, and
(F) separating the jig substrate from the substrate support by the elevation mechanism after the (E), and unloading the jig substrate from the processing container by the transfer robot, and
the (E) further includes (G) supplying the gas into the processing container in a state where a voltage having a polarity opposite to a polarity of the voltage during the (B) is applied to the electrostatic chuck, and neutralizing the charges of the jig substrate placed on the substrate placing surface in a plasma-less manner.

3. The plasma processing system according to claim 2, wherein
the (E) further includes (H) supplying the gas into the processing container in a state where no voltage is applied to the electrostatic chuck, and neutralizing the charges of the jig substrate placed on the substrate placing surface in a plasma-less manner.

4. The plasma processing system according to claim 3, wherein
the (H) is executed after the (G).

5. The plasma processing system according to claim 1, wherein
the gas is an inert gas or an oxygen gas.

6. The plasma processing system according to claim 1, wherein
the plasma processing apparatus further includes another elevation mechanism configured to raise and lower the annular member relative to the substrate support,
the transfer robot is also configured to transfer the annular member, and
the control circuitry further executes:
(I) separating the annular member from the substrate support by the another elevation mechanism when the height of the annular member estimated in the (D) is lower than a threshold value, and unloading the annular member from the processing container by the transfer robot, and
(J) loading an annular member for replacement into the processing container by the transfer robot and placing the annular member for replacement on the substrate support by the elevation mechanism after the (I).

7. The plasma processing system according to claim 1, further comprising:
a member storage configured to store the annular member, wherein
the member storage is connected to the reduced-pressure transfer apparatus.

8. The plasma processing system according to claim 1, further comprising:
an atmospheric pressure transfer apparatus connected to the reduced-pressure transfer apparatus via a load-lock apparatus configured to switch an inner space between an atmospheric pressure atmosphere and a pressure-reduced atmosphere, and the atmospheric pressure transfer apparatus includes a transfer device that operates under an atmospheric pressure atmosphere and that transfers the substrate, and
a member storage connected to the atmospheric pressure transfer apparatus and configured to store the annular member.

9. The plasma processing system according to claim 1, wherein
the jig substrate is stored in the member storage.

10. The plasma processing system according to claim 1, further comprising:
an atmospheric section connected to the reduced-pressure transfer apparatus via a load-lock apparatus configured to switch an inner space between an atmospheric pressure atmosphere and a pressure-reduced atmosphere, and the atmospheric section operates under an atmospheric pressure atmosphere, wherein
the jig substrate is stored in a storage container placed in the atmospheric section and configured to store substrates, or stored in a substrate storage provided in the atmospheric section separately from the storage container.

11. The plasma processing system according to claim 1, wherein
the annular member is an edge ring disposed to be adjacent to the substrate on the substrate support, or a cover ring disposed to cover an outer surface of the edge ring.

12. The plasma processing system according to claim 1, wherein
in the (C), the holder is moved above the substrate support such that the distance sensor crosses the annular member in a plan view, and the distance sensor measures the distance to the reference surface of the jig substrate placed on the substrate placing surface, and continuously measures the distance to the annular member attached to the substrate support, and
in the (D), a profile of the height of the annular member in the cross direction is estimated based on a measurement result of the distance to the reference surface and a measurement result of the distance to the annular member in the (C).

13. A method for estimating a height of an annular member in a plasma processing system which includes a plasma processing apparatus, and a reduced-pressure transfer apparatus connected to the plasma processing apparatus and including a transfer robot configured to transfer a substrate, the plasma processing apparatus including a processing container configured to be depressurized, a substrate support which is provided in the processing container and includes a substrate placing surface and an electrostatic chuck configured to electrostatically attract the substrate to the substrate placing surface, and to which the annular member is attached so as to surround the substrate placing surface, and an elevation mechanism configured to raise and lower the substrate relative to the substrate placing surface, the transfer robot including a holder configured to hold the substrate to be transferred, and a distance sensor provided on the holder and configured to measure a distance from the holder, the method comprising:
(A) loading a jig substrate having a reference surface serving as a reference of the height of the annular member into the processing container by the transfer robot and placing the jig substrate on the substrate support by the elevation mechanism,
(B) applying a voltage to the electrostatic chuck in a state where a gas is supplied into the processing container and attracting the jig substrate to the substrate placing surface in a plasma-less manner,
(C) positioning the holder of the transfer robot above the substrate support and measuring, by the distance sensor, a distance to the reference surface of the jig substrate placed on the substrate placing surface and a distance to the annular member attached to the substrate support, and
(D) estimating the height of the annular member based on measurement results of the distance to the reference surface and the distance to the annular member.

14. The method according to claim 13, further comprising:
(E) supplying the gas into the processing container, and neutralizing charges of the jig substrate placed on the substrate placing surface in a plasma-less manner; and
(F) separating the jig substrate from the substrate support by the elevation mechanism after the (E), and unloading the jig substrate from the processing container by the transfer robot, and
the (E) further includes (G) supplying the gas into the processing container in a state where a voltage having a polarity opposite to a polarity of the voltage during the (B) is applied to the electrostatic chuck, and neutralizing the charges of the jig substrate placed on the substrate placing surface in a plasma-less manner.

15. The method according to claim 14, wherein
the (E) further includes (H) supplying the gas into the processing container in a state where no voltage is applied to the electrostatic chuck, and neutralizing the charges of the jig substrate placed on the substrate placing surface in a plasma-less manner.

16. The method according to claim 15, wherein
the (H) is executed after the (G).

17. The method according to claim 13, wherein
the plasma processing apparatus further includes another elevation mechanism configured to raise and lower the annular member relative to the substrate support, and
the method further comprises:
(I) separating the annular member from the substrate support by the another elevation mechanism when the height of the annular member estimated in the (D) is lower than a threshold value, and unloading the annular member from the processing container by the transfer robot, and
(J) loading an annular member for replacement into the processing container by the transfer robot and placing the annular member for replacement on the substrate support by the elevation mechanism after the (I).

18. The method according to claim 13, wherein the plasma processing system further comprises:
an atmospheric pressure transfer apparatus connected to the reduced-pressure transfer apparatus via a load-lock apparatus configured to switch an inner space between an atmospheric pressure atmosphere and a pressure-reduced atmosphere, and the atmospheric pressure transfer apparatus includes a transfer device that operates under an atmospheric pressure atmosphere and that transfers the substrate, and
a member storage connected to the atmospheric pressure transfer apparatus and configured to store the annular member.

19. The method according to claim 13, further comprising:
an atmospheric section connected to the reduced-pressure transfer apparatus via a load-lock apparatus configured to switch an inner space between an atmospheric pressure atmosphere and a pressure-reduced atmosphere, and the atmospheric section operates under an atmospheric pressure atmosphere, wherein
the jig substrate is stored in a storage container placed in the atmospheric section and configured to store substrates, or stored in a substrate storage provided in the atmospheric section separately from the storage container.

20. The method according to claim 13, wherein
in the (C), the holder is moved above the substrate support such that the distance sensor crosses the annular member in a plan view, and the distance sensor measures the distance to the reference surface of the jig substrate placed on the substrate placing surface, and continuously measures the distance to the annular member attached to the substrate support, and
in the (D), a profile of the height of the annular member in the cross direction is estimated based on a measurement result of the distance to the reference surface and a measurement result of the distance to the annular member in the (C).
